(19) United States
(12) Patent Application Publication
(10) Pub. No.: US 2012/0206269 A1
(43) Pub. Date: Aug. 16, 2012

(54) Electronic System to Signal Proximity of an Object

(75) Inventors: Randy William Wickman, Beaver, PA (US); Thomas Michael Yantek, Lawrence, PA (US); Anthony Kenneth Gianettino, Canonsburg, PA (US); Joseph Mark Mulcahy, Beaver Falls, PA (US); Timothy U. Craddock, Duquesne, PA (US); Songfeng Guo, Cheswick, PA (US)

(73) Assignee: B.E.A. Inc., Pittsburgh, PA (US)

(21) Appl. No.: 13/370,721

(22) Filed: Feb. 10, 2012

Related U.S. Application Data
(60) Provisional application No. 61/441,804, filed on Feb. 11, 2011.

(51) Int. Cl. G08B 21/00; G01R 27/26

(52) U.S. Cl. 340/686.6; 324/679

(57) ABSTRACT

A system to signal proximity of at least one object or entity comprises reference means, sensing means for sensing the at least one object or entity in an electric field, and processing means for detecting at least one capacitive change in at least a portion of the electric field. The sensing means is configured to at least partially form the electric field with at least a portion of the reference means. Also provided is a sensing device comprising at least one electrically conductive unit, at least one reference, and an electrical circuit coupled to at least one processor. At least one of the electric circuit and the at least one processor is configured to cause the at least one electrically conductive unit and the at least one reference to form a capacitive relationship, and detect a capacitive change in at least a portion of the electrical field.

### CROSS REFERENCE TO RELATED APPLICATIONS

This application claims the benefit of U.S. Provisional Patent Application No. 61/441,804, filed Feb. 11, 2011, which is incorporated herein by reference in its entirety.

### BACKGROUND OF THE INVENTION

1. Field of the Invention

The present invention relates to proximity sensors and, in particular, an electronic system to sense the proximity of an object or entity and to request a change of the functional state of an electronic device.

2. Description of Related Art

Well-known capacitive sensing technology requiring personal physical contact includes touch screens for personal data assistants, cellular phones, and music entertainment devices. Other, contact-required, capacitive coupling applications include physical touch light switches in lamps, in display cabinets, and in wall switch mounts. Well-known capacitive proximity sensors are used in manufacturing lines to detect fluid levels or objects with large dielectric differences. These applications have fixed physical sensor sizes and sensor detection distances.

Touch-sensors that are heavily used tend to spread germs and diseases, especially in medical environments. The requirement that these sensors be physically touched may prevent them from being used in devices arranged in sanitary environments, such as automatic faucets, light switches, toilets, and doors for restrooms or medical facilities.

Further, many touch-sensors are prone to wearing out from repeated, high-volume use due to the use of physical switching mechanisms. Physical switches also require a certain degree of mobility and dexterity to activate, making it difficult or impossible for some handicapped or physically challenged individuals to utilize.

Well-known sensing technology that does not require personal physical contact includes passive infrared sensors (PIR) used to turn on lights in consumer appliances, or to protect objects in security applications. These sensors currently do not have the ability to take on two-dimensional flat shapes, three-dimensional shapes, hidden shapes, or user-defined shapes.

Accordingly, a need exists for an electronic system to sense the proximity or presence of an object or entity that does not require physical contact, and that has the ability to take on three-dimensional sensing areas.

### SUMMARY OF THE INVENTION

It is, therefore, an object of the present invention to provide for a device, system and method for sensing the proximity or presence of an object or entity that addresses and overcomes some or all of the drawbacks and deficiencies associated with known proximity or capacitive-touch sensors.

According to one preferred and non-limiting embodiment of the present invention, provided is a sensing device comprising: at least one electrically conductive unit; an electrical circuit coupled to at least one processor, the at least one electrically conductive unit, and at least one reference, wherein the sensing device is configured to: cause the at least one electrically conductive unit and the at least one reference to form a capacitive relationship associated with an electrical field; detect a capacitive change in at least a portion of the electrical field; and cause a functional state of at least one electronic device to be at least partially changed based at least partially on the capacitive change.

According to another preferred and non-limiting embodiment of the present invention, provided is a method for sensing proximity of an object, the method comprising: producing, with at least one electrically conductive unit, a dielectric field by causing at least a portion of the electrically conductive unit to become capacitively coupled with at least one reference, wherein the at least one reference is at least one of the following: ground, a different electrically conductive unit, or any combination thereof; detecting at least one capacitive change in at least a portion of the dielectric field; and changing a functional state of at least one electrical device based at least partially on the at least one capacitive change.

According to a further preferred and non-limiting embodiment of the present invention, provided is a system to signal proximity of at least one object or entity, comprising: reference means; sensing means for sensing the at least one object or entity in an electric field, the sensing means configured to at least partially form the electric field with at least a portion of the reference means; and processing means for detecting at least one capacitive change in at least a portion of the electric field.

These and other features and characteristics of the present invention, as well as the methods of operation and functions of the related elements of structures and the combination of parts and economies of manufacture, will become more apparent upon consideration of the following description and the appended claims with reference to the accompanying drawings, all of which form a part of this specification, wherein like reference numerals designate corresponding parts in the various figures. As used in the specification and the claims, the singular form of “a”, “an”, and “the” include plural referents unless the context clearly dictates otherwise.

### BRIEF DESCRIPTION OF THE DRAWING(S)

FIG. 1 is a block diagram of a proximity sensing system according to the principles of the present invention;

FIG. 2a is a schematic diagram of a portion of an electrical circuit for connecting a sensing means to a processing means for a system according to the principles of the present invention;

FIG. 2b is a further embodiment of the circuit diagram of FIG. 2a;

FIG. 3a is a schematic diagram of a portion of an electrical circuit associated with the processing means of a system according to the principles of the present invention;

FIG. 3b is a further embodiment of the circuit diagram of FIG. 3a;

FIG. 4 is a schematic diagram of a portion of an electrical circuit for power conditioning for a system according to the principles of the present invention;

FIG. 5a is a schematic diagram of an indication means for a system according to the principles of the present invention;

FIG. 5b is a schematic diagram of a further embodiment of the indication means of FIG. 5a;

FIG. 5c is a schematic diagram of a further embodiment of the indication means of FIG. 5a;

FIG. 6a is a schematic diagram of a relay means for a system according to the principles of the present invention;

FIG. 6b is a schematic diagram of a further embodiment of the relay means of FIG. 6b;

FIG. 7a is a schematic diagram of an input means for a system according to the principles of the present invention;

FIG. 7b is a schematic diagram of an input means for a system according to the principles of the present invention;

FIG. 8a is front perspective view of a proximity sensing system according to the principles of the present invention;

FIG. 8b is a back perspective view of the proximity sensing system shown in FIG. 8a;

FIG. 9a is a front perspective view of a further embodiment of a proximity sensing system according to the principles of the present invention;

FIG. 9b is a back perspective view of the proximity sensing system shown in FIG. 9a;

FIG. 10 is a side view of the proximity sensing system shown in FIGS. 8a and 8b;

FIG. 11 is a front and back perspective view of a sensing means for a proximity sensing system according to the principles of the present invention;

FIG. 12 is a schematic diagram for a further embodiment of an electrical circuit for a proximity sensing system according to the principles of the present invention; and

FIG. 13 is a flow diagram for a determination and detection routine for a proximity sensing system according to the principles of the present invention.

### DESCRIPTION OF THE PREFERRED EMBODIMENT(S)

The present invention will be described with reference to the accompanying figures where like reference numbers correspond to like elements.

For purposes of the description hereinafter, the terms “end”, “upper”, “lower”, “right”, “left”, “vertical”, “horizontal”, “top”, “bottom”, “lateral”, “longitudinal” and derivatives thereof shall relate to the invention as it is oriented in the drawing figures. It is also to be understood that the specific devices and processes illustrated in the attached drawings, and described in the following specification, are simply exemplary embodiments of the invention. Hence, specific dimensions and other physical characteristics related to the embodiments disclosed herein are not to be considered as limiting. Further, it is to be understood that the invention may assume various alternative variations and step sequences, except where expressly specified to the contrary.

The present invention is directed to an electronic system or device (hereinafter individually and collectively referred to as “the system”) for detecting the proximity or presence of an object or entity, and/or detecting a request to change the functioning state of an electronic device that addresses or overcomes some or all of the deficiencies and drawbacks discussed above in connection with sensor technology.

Advantages of the system according to the principles of the present invention include an ability to be used in high volume switching, since there are no physical switching mechanisms required that may wear out from repeated use. Further advantages relate to use in public areas, where the repeated touching of a physical switch spreads disease, and use by the physically challenged or disabled, because the system requires less personal mobility and dexterity to activate than a physical switch. Other advantages relate to personal safety applications, where the functional state of an electronic device may be automatically changed in an unsafe situation. In cleanroom environments, for example, the touchless feature of the system reduces dust generated from physical contact and wearing of surfaces.

In one preferred and non-limiting embodiment, the present invention is an electronic system for detecting the proximity of an object or entity, and/or detecting a request to change the functioning state of an electronic device. This electronic system is a size-scalable proximity-sensor system or device for detecting a request to change the functioning state of an electronic device 6. The operational request is made by changing the capacitive coupling of a unit associated with the system by, for example, sensing an object or entity in proximity to the unit of the system 1, or by sensing physical contact. Operation of the system may be either a deliberate personal act, or may occur without the knowledge of an entity within proximity to the device. A person toggling a light switch, or pushing a button to turn on or turn off lighting, or to open, close or stop the motion of a physical object such as a door, are possible functions.

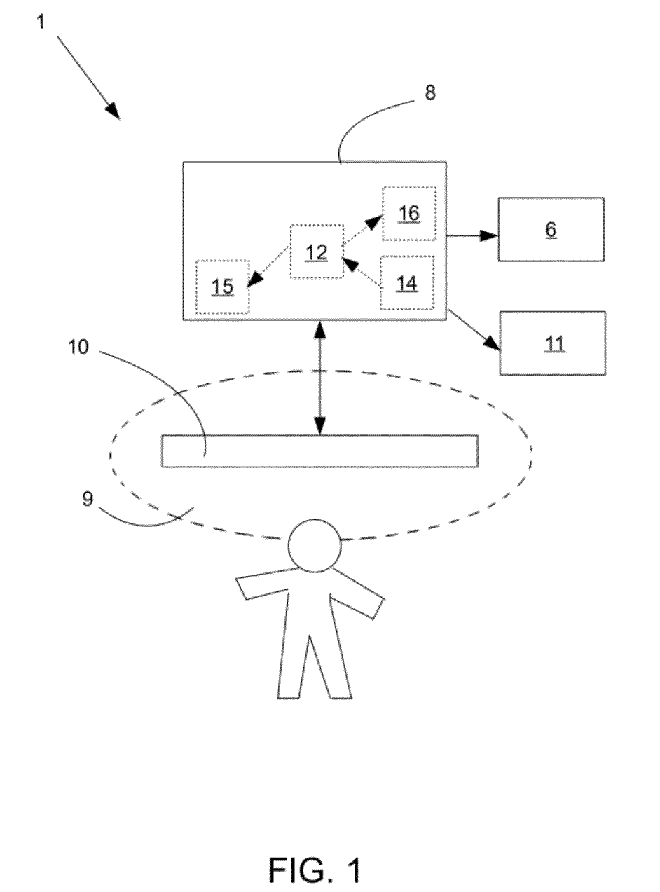

Referring now to FIG. 1, a system 1 for signaling the proximity or presence of an object or individual is shown according to a preferred and non-limiting embodiment of the present invention. The system 1 includes reference means 11, sensing means 10 for sensing an object or entity in an electric field and for forming an electric field 9 with the reference means 11, and processing means 12 for detecting changes in at least a portion of the electric field 9. The sensing means 10 may comprise at least one electrically conductive material configured to, at least partially, produce an electric field 9 with the reference means 11. The processing means 12 may be coupled to the reference means 11 and the sensing means 10. The system 1 may also include an electrical circuit 8 coupled to the processing means 12. The electrical circuit 8 and/or the processing means 12 are further coupled to the sensing means 10 and the reference means 11. The electrical circuit 8 and/or processing means 12 are configured to cause the electrically conductive unit 10 to become capacitively coupled with the reference 11, forming the electric field 9.

With continued reference to FIG. 1, an object or entity (in this case, an individual) may enter the electric field 9, thus changing the capacitance of the electric field 9. The change in capacitance is detected by the processing means 12, which in turn causes a functional state of an electronic device 6 to be changed. For example, the functional state may include, but is not limited to, on, off, start, stop, stall, increase, decrease, dim, brighten, or any other functional state associated with an electronic device 6. The electronic device 6 may include controlled entryways, doors, windows, lights, manufacturing devices and arrangements, fixtures, appliances, or other equipment. However, it will be appreciated that any number of electronic devices may be used in connection with the system 1.

The sensing means 10 may include one or more electrically conductive materials and may be referred to as an electrically conductive unit 10. For example, the sensing means 10 may include common building materials such as steel, aluminum, and copper. The sensing means 10 may also include non-metallic materials, such as plastics, glasses, papers, and textiles, having metal-coated films, or comprising carbon or metallic blends. Semiconductor materials may also be used that include, for example, silicon, germanium, or mixtures of arsenic, tellurium, and selenium. It will be appreciated by one skilled in the art that the sensing means 10 may take on any number of forms, including solids, liquids, and/or gaseous materials having some form of electrical conductivity. Further, the sensing means 10 may take on a variety of shapes, including flat (e.g., plates, signs, or other flat objects) and three-dimensional. In a preferred and non-limiting embodiment, the sensing means 10 includes a conductive plate.

The reference means 11 may include any electrically conductive material or reference electrode, including but not limited to an internal potential reference or circuit ground (e.g., signal ground or chassis ground), or an external potential reference, such as earth or building ground, or a conductive material. In a preferred and non-limiting embodiment, the reference means 11 is building or earth ground. The reference means 11 is coupled to an electrical circuit 8 and/or processing means 12 or other devices, such that the reference means 11 becomes capacitively coupled to the sensing means 10. In some instances, building or earth ground may not be accessible to the system 1. In a further non-limiting embodiment, the reference means 11 is a conductive wire that extends from the system 1.

As used herein, the term “coupled” refers to any direct or indirect connection between more than one reference point or object and may include, for example, a connection between two components through one or more intermediary connections. Further, “coupled” refers to both wired and wireless connections, including direct and indirect connections.

As used herein, the terms “capacitive coupling” and “capacitively coupled” refer to an electrical relationship between one or more materials between which energy is transferred. The relationship between the materials forms a capacitor such that an electrical field 9 is formed between the materials. The electrical field or dielectric region 9 may be two or three dimensional, depending on the materials used and the respective placement of the materials.

As used herein, the terms “electric field,” “electrical field,” and/or “dielectric region” 9 refer to an area or volume (i.e., two or three-dimensional) in which energy is transferred between two capacitively coupled units. This area or volume may also be referred to as a “capacitive field” or “sensing region.” In the context of the system according to the principles of the present invention, the units include the electrically conductive unit 10 (e.g., sensing means) and reference means 11. The electric field 9 may be associated with a capacitance, created from the capacitive coupling. The capacitance of the electric field 9 may have a baseline value or range for a normal operating environment, where the dielectric medium is air or other matter positioned between the units or in proximity to the units that affects the capacitance between the two units. Thus, changes in the capacitance of the electric field 9 that fall above or below the baseline value or range may indicate that the matter in the dielectric region has shifted, changed, or otherwise been altered. This chance in capacitance may then be used to detect the proximity or presence of an object or entity in relation to the electrically conductive unit 10.

The electric field 9 (e.g., dielectric region) may be two or three-dimensional, based on the arrangement of the electrically conductive unit 10 and reference 11, and sensitivity adjustments. For example, the electric field 9 may be two-dimensional on a surface of the electrically conductive unit 10 that experiences a change in capacitance only when an entity or object makes physical contact with the electrically conductive unit 10. In another example, the reference 11 and electrically conductive unit 10 may be arranged to produce a three-dimensional electric field 9 associated with a capacitance.

In one preferred and non-limiting embodiment of the present invention, the electric field 9 may be closely confined to the sensing means (e.g., 6 inches away). Such a distance may help reduce interference associated with parallel traffic, thus reducing unintended operation or change in state of the electronic device 6.

The electrical circuit 8 and/or processor 12 may be further configured to receive a measurement of the capacitance of the electric field 9, and detect changes in this capacitance. The electrical circuit 8 and/or the processor 12 may then compare a baseline value or range of the capacitance of the electric field 9 to the capacitance of the electric field at any given time, measured continuously or intermittently. If one or more values associated with the capacitive changes reach a predefined threshold amount (e.g., deviating a predetermined amount from the baseline value or range), the sensing device may then react in a predetermined way. In one preferred and non-limiting embodiment, the sensing device reacts by changing the functional state of one or more electronic devices 6. For example, the system 1 may react to changes in the electric field 9 by causing an electric door or window to open or close.

The processing means 12 may include one or more processors or microprocessors, or may include a computer system or other data processing system including one or more processors or microprocessors. The processing means 12 may be coupled to the sensing means 10, the electrical circuit 8, the reference means 11, input means 14, indication means 15, relay means 16 and other components. The processing means 12 may include one or more internal oscillators to obviate the need for external oscillators in the electrical circuit 8. One example of a processing means 12 suitable for carrying out the tasks associated with the present invention is a PIC16LF1827 microprocessor. However, it will be appreciated that any number of processors, microprocessors, or other processing means may be implemented.

In a preferred and non-limiting embodiment of the present invention, the system 1 includes relay means 16 for changing a functional state of an electronic device 6, or otherwise controlling an electronic device 6. For example, the functional state may be changed to on, off, start, stop, stall, increase, decrease, bright, dim, and other like functional states. The electronic device 6 may include controlled entryways, doors, windows, lights, manufacturing devices and arrangements, fixtures, appliances, or other equipment.

The relay means 16 may be a solid-state relay, allowing for the system 1 to change the functional state or otherwise activate the electronic device 6. The relay means 16 may include, for example, semiconductor components such as an Opto FET, semiconductor relay, wireless transmitter, or silicon control rectifier (SCR). The relay means may transmit a signal to an electronic device 6 or a receiver, indicating a desired functional state or condition. However, it will be appreciated that the relay means 16 may also be in the form of an electromechanical switch or any other device or component capable of changing a functional state or otherwise activating an electronic device 6.

When an entity (e.g., person) or object enters the electric field 9, as defined by the location of the sensing means 10 and reference means 11, the capacitive coupling is changed and, based on that change, the system 1 performs an electronic switch operation to change the functional state of an electronic device 6. To be recognized as a switch by a user, the visible sensing means 10 may take on the shape of a switch or push button, may be a conductive plate placed over a standard building material electronic box, may be placed in a common switch location, or may be signified as a switch by visual indicator, text, symbol, lighting, or by sonic means.

It is possible to disguise the sensing means 10 as on object other than a switch. In a door application, for example, the sensing means 10 may look and function as a door kick plate, a door knob or other fixture, or the door itself. The ability to disguise the sensing means 10 allows for aesthetic, safety, and security advantages. The three-dimensional and contact-free electric field 9 allows the system 1 to blend into an architectural environment. When functioning as a hidden safety device, safety is enhanced, since the sensing means 10 may be hidden from any potential perpetrators. When functioning as a security device, security is enhanced by hiding the sensing means 10 from unscrupulous activity. For example, the sensing means 10 could be an electrically conductive glass panel protecting a valuable article on display. Upon approach by an entity, the dielectric region 9 is altered and the system 1 can signal the altercation by any number of means (e.g., signaling an alarm).

Powering the system 1 may be accomplished with, for example, batteries or utility power. Battery operation allows the system 1 to be used in remote locations, further enhanced by wireless signaling to operate other appliances. This configuration is useful for applications where utility power or wiring is typically not available, such as on a moving object (e.g., a door). In a door application, the system 1 may open the door because of limited personal mobility or for safety applications, may stop the door from contacting an object in the door path, or may enhance other safety functions or operations. When the battery power starts to fail, the processing means 12 transmits to a signaling unit that includes a sonic device or LED that the batteries need to be changed.

In locations where utility power is not established, battery-based applications may include retrofitted wall switches and wireless communication to powered appliances, such as, but not limited to, a ceiling fan. The sensing means' 10 ability to take on non-typical shapes and locations allows for a wide field of applications and configurations.

In a preferred and non-limiting embodiment, the system 1 of the present invention may be used in connection with bathroom fixtures. The fixtures themselves may be the sensing means 10, obviating the need for infrared (IR) sensors which require one to make a motion in a specific location. If conductive appliances or fixtures are made into the sensing means 10, or if the sensing means 10 are otherwise incorporated into such appliances or fixtures, a person would only have to get their hands close to any location on a water faucet, for example, and the system would turn on the water. Moving one's hands away from the faucet would turn it off. It will be appreciated that this arrangement may be employed with a paper towel dispenser, an air dryer, a soap dispenser, a toilet flushing mechanism, and other like devices.

In one non-limiting embodiment of the present invention, hermetic sealing, plastic potting, or conformal coating protects the system's circuitry in certain environmental conditions, such as high humidity or direct contact with water facilities, thus permitting effective use in both indoor and outdoor applications. Wireless signaling to electronic appliances enhances this advantage.

In a preferred and non-limiting embodiment of the present invention, the processing means 12, or some other processing device coupled to the electrical circuit 8, may be adapted to learn the sensing environment through one or more learning cycles. The processing means 12 receives input from the sensing means 10 and learns a capacitive coupling reference value (i.e., a baseline value or range) between the sensing means 10 and the reference means 11. During the learning cycle, all objects or other matter within the detection field are learned as the nominal (e.g., baseline) static environment.

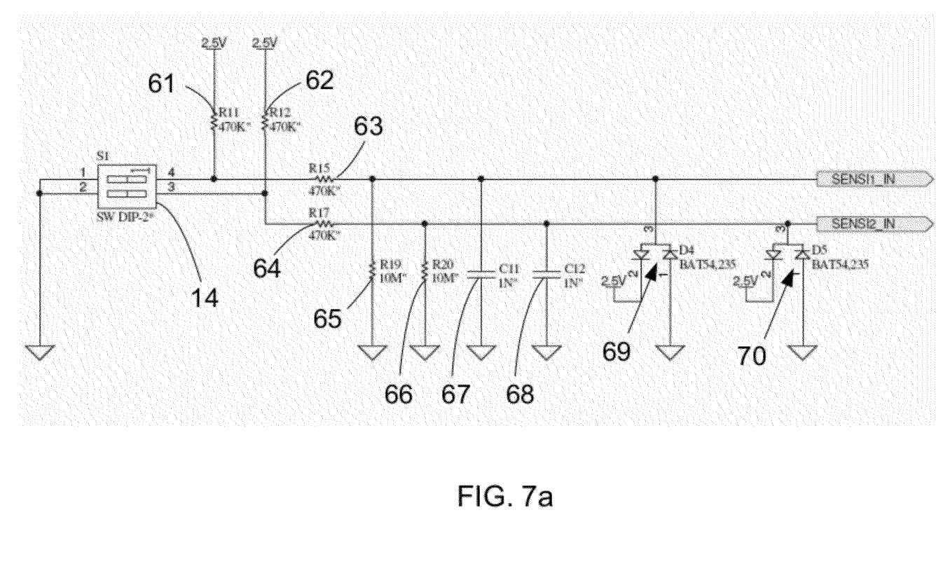

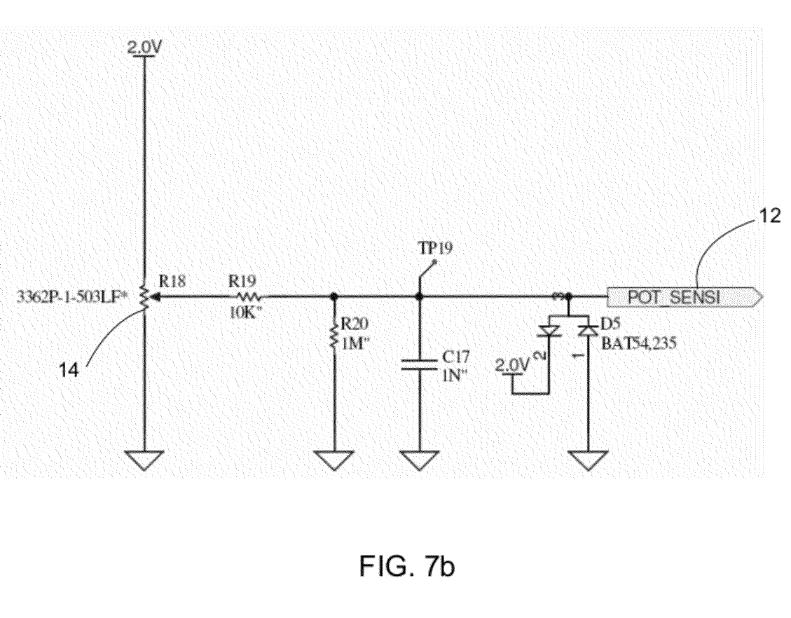

The processing means 12 may be further configured to process data relating to the sensing means 10, reference means 11, and the surrounding environment. This data processing enables the device or system 1 to learn a baseline value or range associated with the electrical field 9. The processing means 12 may then re-learn the quasi-static environment as changes occur in temperature, humidity, and/or the physical surroundings. The device or system 1 may provide input means 14, similar to that shown in FIGS. 7a and 7b, for adjusting the learning cycle in the field.

The indication means 15 may include, for example, a sound-emitting device (e.g., an alarm or “buzzer”), a light-emitting device (e.g., a light-emitting diode (LED)), or any other device capable of alerting or indicating that the system 1 is in use, is connected to a power source, or has detected proximity and/or the presence of an object or entity. For example, an LED may indicate that the device is on and operable. A sound-emitting device may indicate that someone or something has entered the electrical field 9 with an audible alarm. It will be further appreciated that the indication means 15 may be one or more types of indicators. For example, an LED and a sound-emitting device may both be employed.

The indication means 15 may be chosen and implemented based on the intended use of the sensing device. For example, a sound-emitting device may be utilized in applications where visually-impaired persons may be using the electronic device 6, such as an automatic door. The sound-emitting device may produce an audible “click” to indicate proximity of a person or object. Further, an LED or other visual indicator may be employed in applications where hearing-impaired persons may be using the electronic device 6.

In one preferred and non-limiting embodiment, the indication means 15 includes one or more LEDs in a rear portion of the sensing means 10, or in a rear portion of a mounting means 72 associated with the sensing means 10. The LEDs thus positioned may create a glow or illumination behind the sensing means 10 on a surface, such as a wall. In one preferred and non-limiting embodiment, the LEDs emit a substantially blue light that may include any shade or hue of blue. However, it will be appreciated that the LEDs may be any number of colors and may be positioned in any number of ways.

In a further, non-limiting embodiment of the present invention, the system 1 further includes an accelerometer coupled to the electrical circuit 8 and/or the processing means 12. The accelerometer allows the system 1 to determine whether the sensing means 10 or other component of the system 1 has been physically contacted and/or impacted. The accelerometer may account for instances of contact that are too quick to detect a change in capacitance of the electric field 9, or for instances where the change in capacitance is too minimal to be recognized. This feature may serve as a redundency, in case the system 1 malfunctions, or used in emergency situations.

One or more LEDs may be on during normal operation of the device, when the electric field 9 is at a baseline level and no change or proximity is detected, and switch off when an object or entity is detected. The LEDs may illuminate the plate from behind the plate, or may be situated anywhere on or around the place. In a further embodiment, the LEDs may be off and, when the capacitance of the electric field 9 is within a baseline value or range, turn on when an entity or object is sensed in the electric field 9. The LEDs may be coupled to the electrical circuit 8 or processor 12.

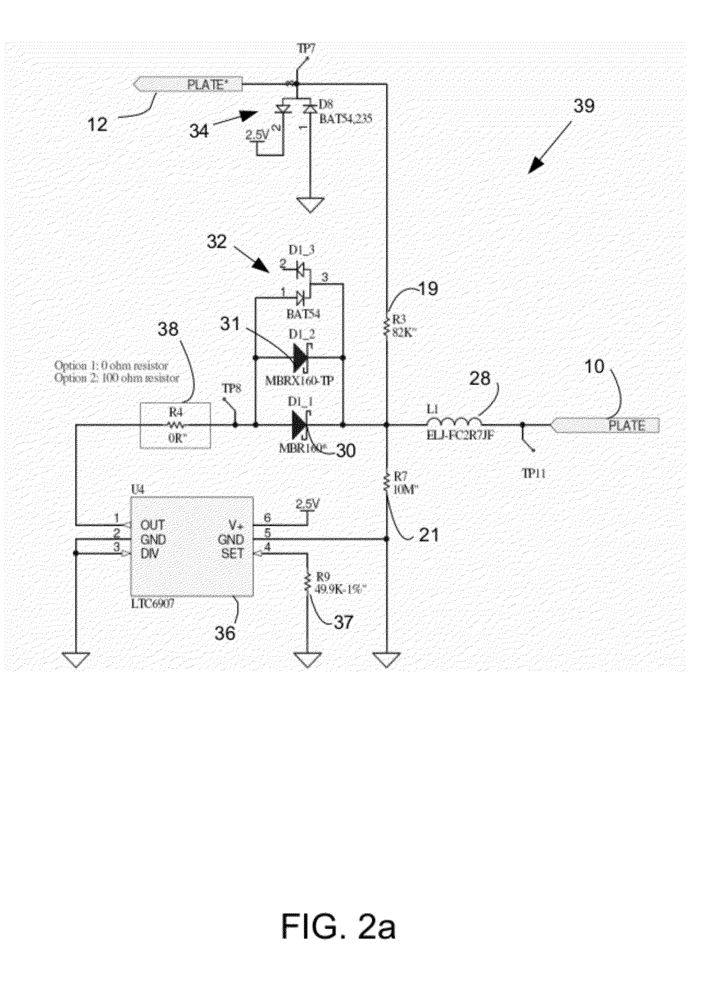

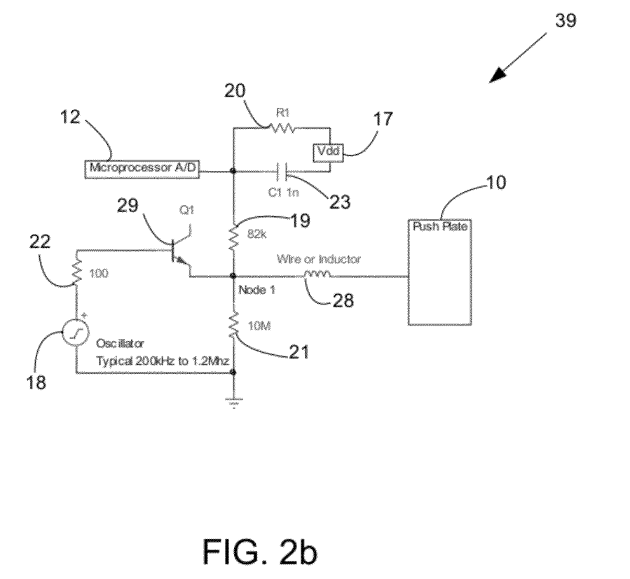

Referring now to FIGS. 2a and 2b, schematic diagrams are shown for a portion 39 of the electrical circuit 8 according to the principles of the present invention. The diagrams shown in FIGS. 2a and 2b illustrate circuits that may be coupled to the processing means 12 and the sensing means 10 (e.g., electrically conductive unit). In both diagrams, an inductor 28 (e.g., a coil, air-core inductor, or other like device that stores energy in a magnetic field) is coupled to the sensing means 10. Although the inductor may take on any number of forms and inductances, a 2.7 microhenries inductor is suitable.

With continued reference to FIG. 2b, the inductor 28 is coupled to resistors 19, 21. Resistor 19 is coupled to resister 21, the processing means 12, a capacitor 23, and a resistor 20. Capacitor 23 and resistor 20 are both coupled to a voltage supply 17 and processing means 12. Resistor 21 is coupled to resister 19 and ground, an oscillator 18, and transistor 29. Oscillator 18 is further coupled to resistor 22, and resister 22 is coupled to transistor 29. In one preferred and non-limiting embodiment, oscillator 18 has a frequency between 200 kHz and 1.2 MHz, resistor 21 is ten (10) megohms, resistor 19 is 82 kilohms, and resistor 22 is 100 ohms. However, it will be appreciated that various different types of components may be used. For example, in one non-limiting embodiment of the present invention, the oscillator 18 may have a frequency of 4 MHz.

Referring now to FIG. 2a, a further embodiment of a circuit for connecting the sensing means 10 to the processor 12 or remainder of the electrical circuit 8 is shown. The inductor 28 is coupled to resistors 19, 21, and the inductor and resistor 19 are coupled to diodes 30, 31, 32. Resistor 19 is coupled with resistor 21, diode 34, and processing means 12. Diode 34 is coupled to processing means 12. Resistor 21 and diode 34 is coupled to ground. Resistor 21 is further connected to a precision programmable oscillator 36 (ground port), such as but not limited to an LTC6907 resistor set oscillator. The programmable oscillator 36 is further coupled to a voltage source (V+ port) and a resistor 37 (set port). Resistor 37 may be, but is not limited to, a 49.9 kilohm resistor, and is coupled to ground. The programmable oscillator 36 out port is further coupled to a resistor 38 (e.g., 0 or 100 ohms), which is coupled diodes 30, 31, 32. Diodes 30, 31, 32 are coupled to each other.

In one non-limiting embodiment of the present invention, the oscillator may be a free-running RC oscillator using two (2) comparators with an SR latch to change the charge direction of the voltage associated with the sensing means 10 up or down. The oscillator will charge between upper and lower limits set by the positive inputs to the comparators. The time required to charge from the lower limit to the upper limit and discharge back to the lower limit may be referred to as the period of the oscillator. Once the oscillator is constructed, its frequency may be monitored to detect a drop in frequency that would indicate proximity of an object or entity, or physical contact with the sensing means 10.

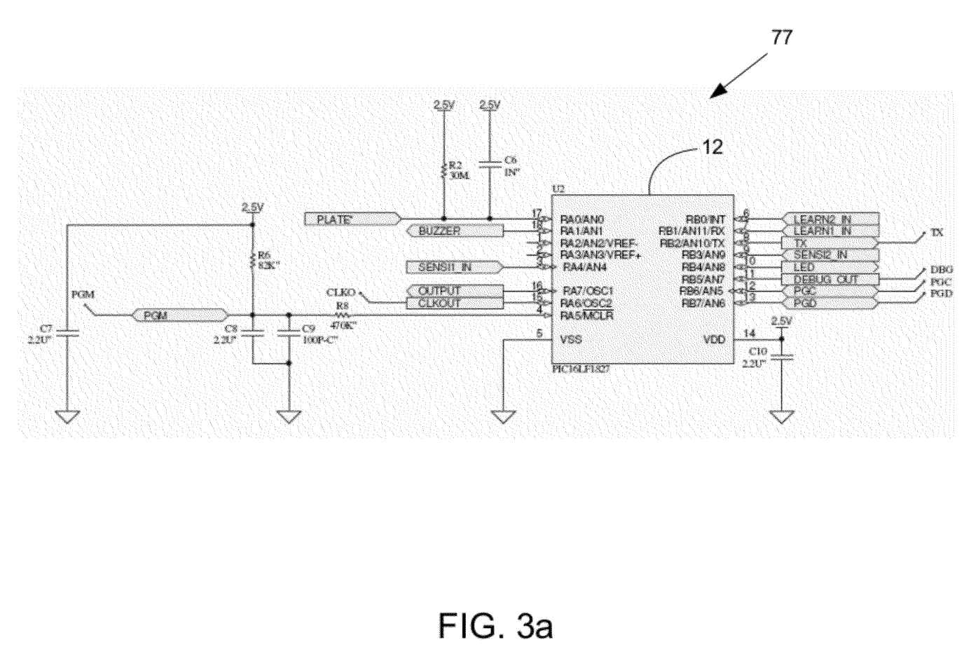

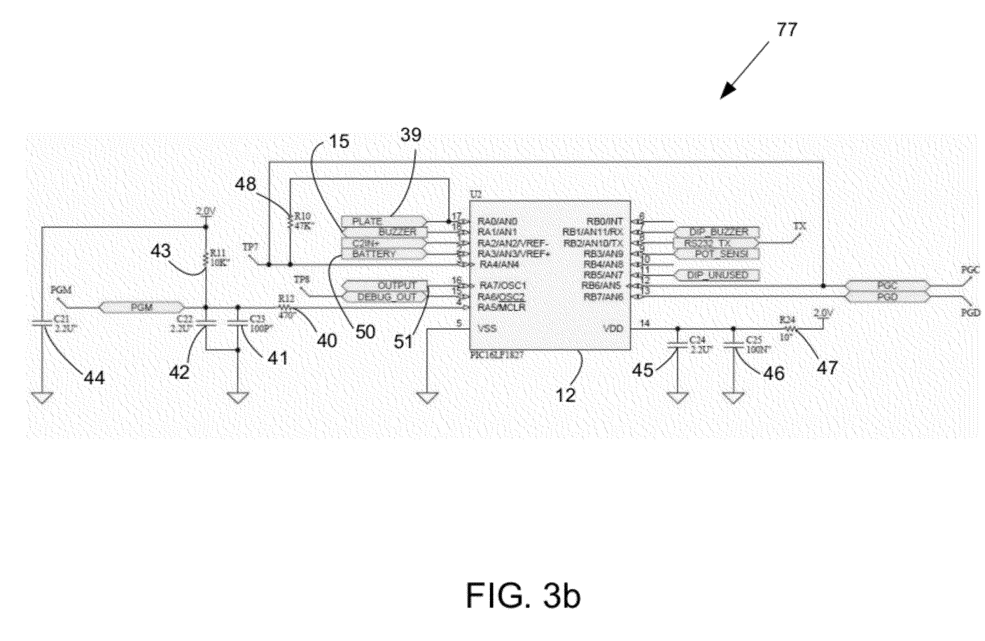

Referring now to FIG. 3b, a schematic diagram is shown for a portion 77 of the electrical circuit 8 associated with the processing means 12 according to the principles of the present invention. The processing means 12 is coupled to the circuit portion 39 associated with the sensing means 10, an indication means 15, a battery 50, and an output circuit 51. FIG. 3b illustrates a circuit that serves as an input to the processing means 12. A resistor 40 (e.g., 470 ohms) is coupled to the processing means 12, a capacitor 41 (e.g., 100 picofarads), a capacitor 42 (e.g., 2.2 microfarads), and a resistor 43 (e.g., 10 kilohms). The capacitor 42 and 41 are further coupled to each other and ground. The resistor 43 is further coupled to a voltage supply and capacitor 44 (e.g., 2.2 microfarads). The processing means 12 is further coupled to a capacitor 45 (e.g., 2.2 microfarads), capacitor 46 (e.g., 100 nanofarads), and resistor 47 (e.g., 10 ohms), which is in turn coupled to a voltage supply. One end of resistor 48 (e.g., 47 kilohms) is coupled to an input of the processing means 12, and the other end of resister 48 is coupled to another input of the processing means 12 and an input of the sensing means 10. Capacitors 45, 46 are coupled to ground. However, it will be appreciated that the components (e.g., capacitors, resistors, etc) may be of various different types.

Referring to FIG. 3a, a further embodiment of a portion 77 of the electrical circuit 8 associated with the processing means 12 is shown. This circuit is similar to that shown in FIG. 3b, with changes to the circuit leading from the power supply terminal (VDD) of the processing means 12. In this example, the power supply terminal port is coupled to a voltage supply and a capacitor (e.g., 2.2 microfarads), and the capacitor is further coupled to ground.

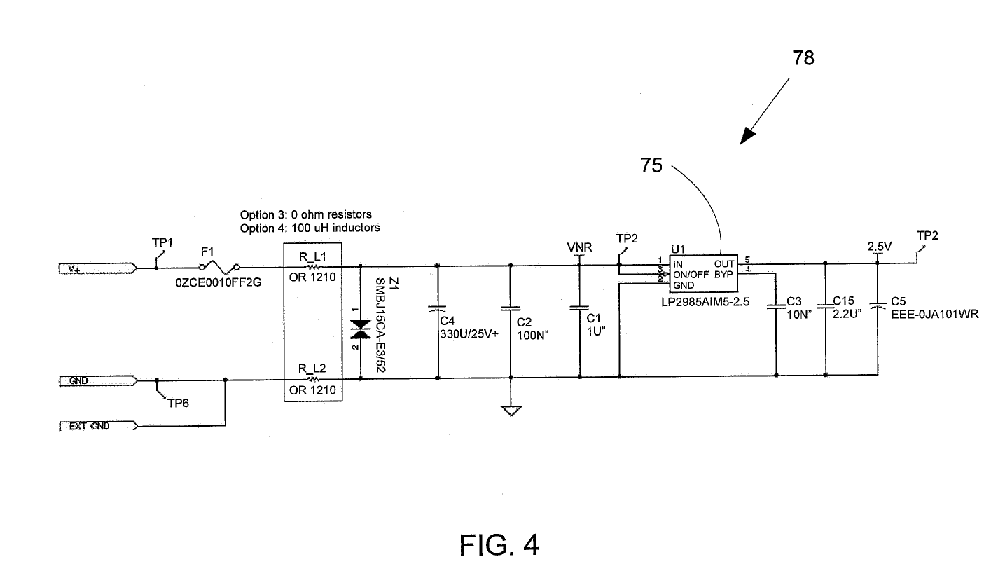

Referring to FIG. 4, a schematic diagram for a portion 78 of the electrical circuit 8 associated with power conditioning is shown. A voltage regulator 75 (U1) is coupled to a series of capacitors, a fuse (F1), resistors (R_L1 R_L2) and a diode (Z1). The power conditioning circuit 78 is adapted to be connected to one or more batteries, a battery pack, or wire leads.

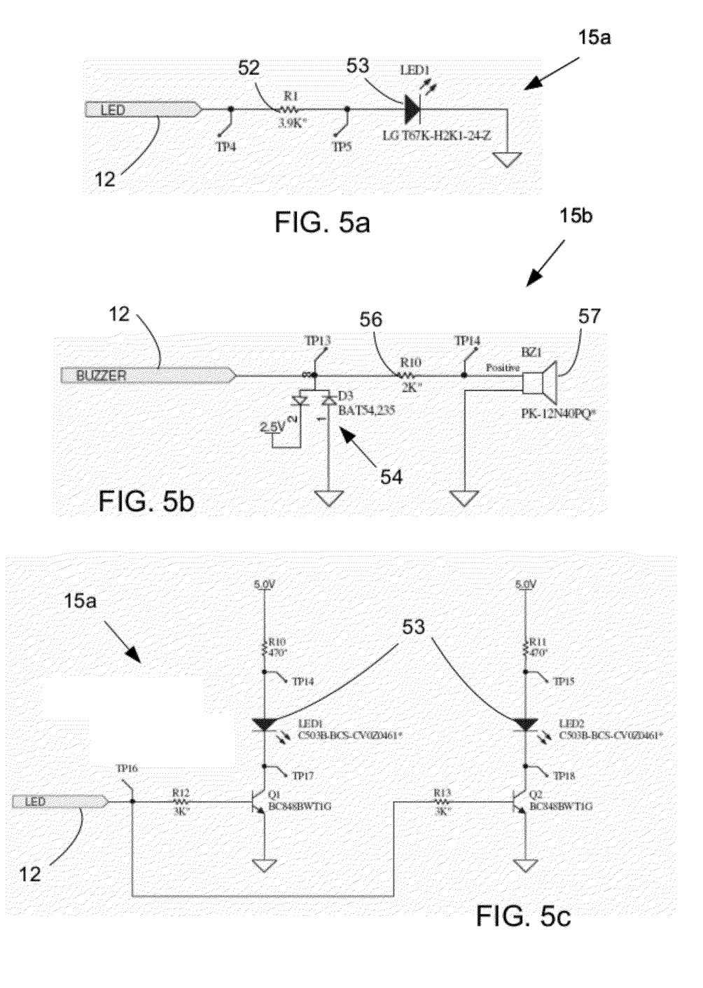

FIG. 5a illustrates a diagram for an indication means 15a according to the principles of the present invention. A resistor 52 is coupled to the processing means 12 and a light emitting diode 53, which is then coupled to ground. FIG. 5b illustrates a schematic diagram for a further indication means 15b according to the principles of the present invention. The processing means 12 is coupled to barrier (double) diode 54. The processing means and diode 54 are further coupled to resistor 56 (e.g., 2 kilohms), which is coupled to a speaker 57, which is then coupled to ground. FIG. 5c illustrates a schematic diagram for a further embodiment of an indication means 15a. The indication means 15a is coupled to the processing means 12 and includes LEDs 53.

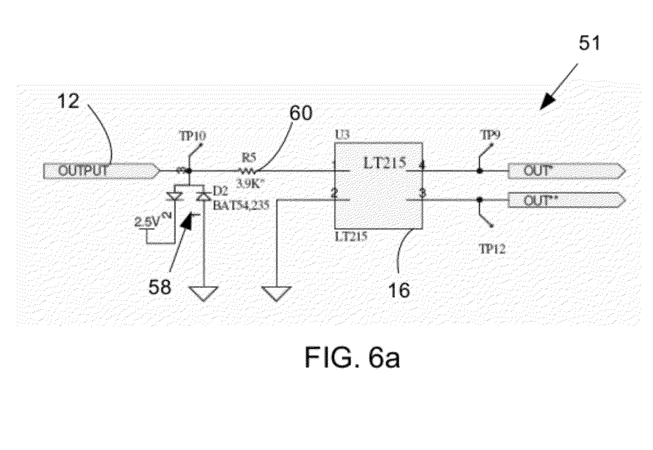

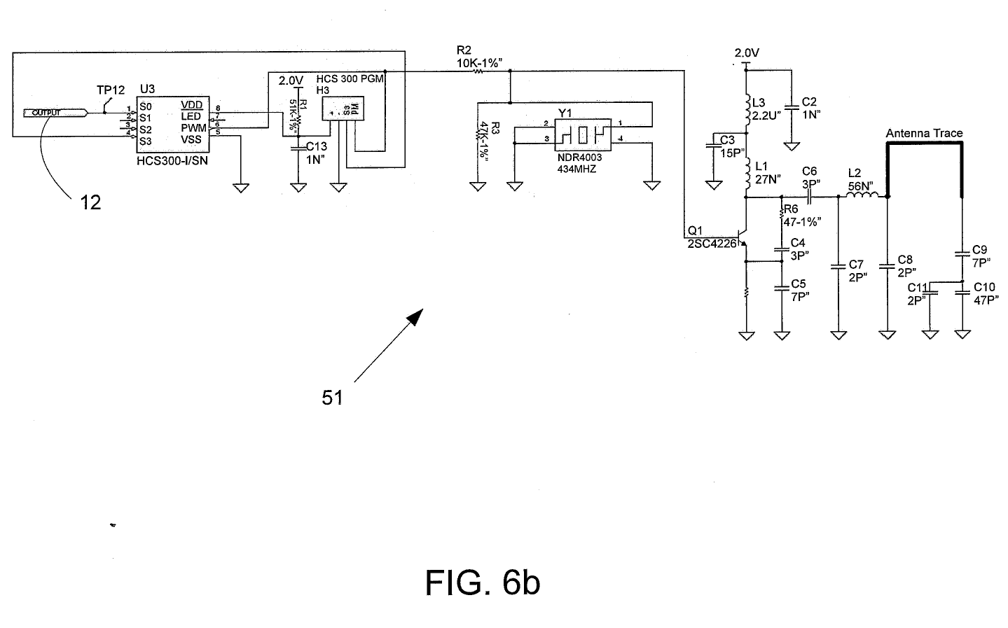

FIG. 6a illustrates a schematic diagram for an output circuit 51 for a system according to the principles of the present invention. The processing means 12 is coupled to diodes 58, and resistor 60 (e.g., 3.9 kilohms). Diode 58 is coupled to a voltage supply and diode 59 is coupled to ground. Resistor 60 is coupled to a relay means 16 for changing the functional state of an electronic device 6 (not shown). The relay means 16 is coupled to the electronic device 6 to be operated or manipulated, or coupled to a terminal block.

FIG. 6b illustrates a schematic diagram for a further non-limiting embodiment of an output circuit 51 for a system according to the principles of the present invention. In the output circuit 51 illustrated by FIG. 6b, a signal is wirelessly transmitted to an electronic device 6 (not shown) to cause a change in a functional state of the electronic device 6. In this example, a 434 MHz signal is used, although it will be appreciated that any number of frequencies and wireless transmission protocols may be used as relay means 16. The output circuit 51 is coupled to the processing means 12.

Referring now to FIGS. 7a and 7b, schematic diagrams for a user input circuit is shown according to the principles of the present invention. An input means 14 is coupled to the processing means 12. The input means 14 may include, for example, a variable resister (e.g., potentiometer), a DIP switch, or any other variable controls capable of facilitating user input. Referring now to FIG. 7a, a first port of a PCB switch 14 (e.g., input means) is coupled to resistor 61 (e.g., 470 kilohms), which is coupled to a similar resistor 63, which is then coupled to resister 65 (e.g., 10 megohms), which is then coupled to ground. Resister 63 is also coupled to capacitor 66 (e.g., 1 nanofarad), which is then grounded, and barrier (double) diode 69. A second port of the PCB switch is coupled to resistor 62 (e.g., 470 kilohms), which is coupled to a similar resistor 64, which is then coupled to resister 66 (e.g., 10 megohms), which is then coupled to ground. Resister 64 is also couple to capacitor 68 (e.g., 1 nanofarad), which is then grounded, and barrier (double) diode 70. The barrier diodes 69, 70 are coupled to the processing means 12.

Referring now to FIG. 7b, a schematic diagram for a further embodiment of a user input circuit is shown according to the principles of the present invention. In this example, a variable resister 14 (e.g., input means) is coupled to the processing means 12 through a circuit. It will be appreciated that several user input circuits or devices could be coupled to the processing device to allow users to set, install, or calibrate the system 1 in the field or elsewhere. For example, the input circuit shown in FIG. 7b may enable users to adjust the touchless sensing distance for a particular application.

In one preferred and non-limiting embodiment of the present invention, the electric field 9 is associated with an adjustable detection/activation range with respect to the sensing means 10. This detection/activation range may be set by a potentiometer or other input means 14 provided by, for example, the user input circuit shown in 7b. The adjustable detection/activation range may allow for a configurable range of, for example, one-half (½) of an inch to six (6) inches. The potentiometer 14 may provide an analog output to the processing means 12, through an analog-to-digital converter input associated with the processing means 12. Thus, by turning the potentiometer 14, a desired range and/or sensitivity may be selected.

Adjusting the sensitivity of the sensing means 10 may be required for different applications and/or users of the system 1. Some applications may require a maximum range/sensitivity to minimize any physical touching of the sensing means 10. This may be important in certain application such as, for example, sanitary environments. Other applications may require a reduced range/sensitivity in order to avoid accidental activations in, for example, a narrow corridor or other environment where unintended activations are likely to occur. Using a potentiometer, users may adjust the sensitivity according to the environment and application of the system 1. The detection range/sensitivity may further be affected by a number of factors, including but not limited to the size and shape of the sensing means 10, individual components, temperature, humidity, and the capacitance and size of the object or entity attempting to activate the sensing means 10.

For instance, the sensing means 10 may seem to have a greater activation range if a person uses a large metal tray (e.g., conductor) to activate the plate as opposed to a roll of paper towels (e.g., insulator). To assess the sensitivity, the processing means 12 uses a function to get an analog reading, and then uses the analog value as the x-value in a straight line equation (e.g., y=mx+b) to interpolate the y-value. The y-value will be a deviation from the capacitance baseline learned by the processing means 12 from the sensing means 10.

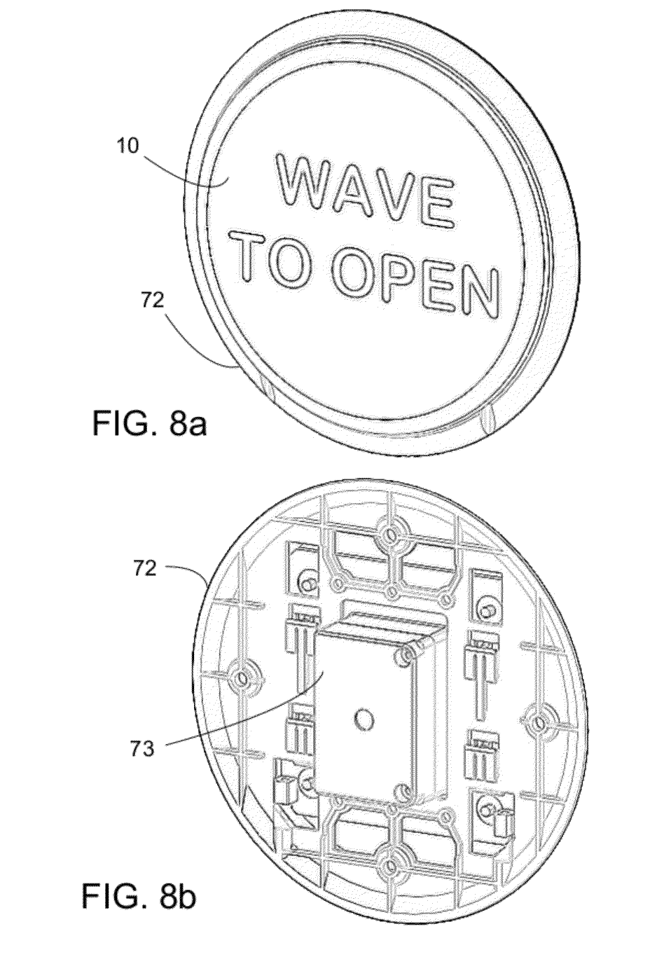

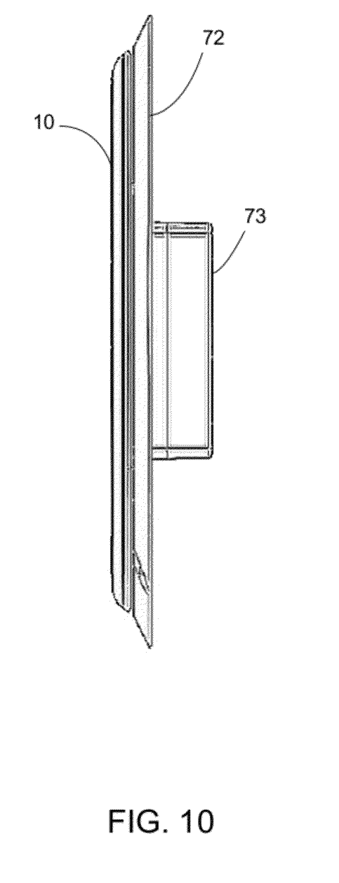

Referring now to FIGS. 8a, 8b, and 10, a non-limiting embodiment of the system 1 is shown according to the principles of the present invention. The system 1 includes sensor mounting means 72 for securing the sensor means 10. The system 1 may further include a containment means 73 for containing at least some of the electronic components associated with the device. The mounting means 72 and/or the containment means may be adapted to be installed on a wall, in an electrical box, or elsewhere.

In FIG. 8a, a sensing means 10, in this example a conductive plate, is mounted to a sensor mounting means 72. Referring to FIG. 8b, which illustrates a back-side view of the sensor device in FIG. 8a, the sensor mounting means 72 allows for a containment means 73 to extend from the sensing means 10, through an aperture in the sensor mounting means 72. The containment means 73 may contain some or all of the various components including, but not limited to, the electrical circuit 8 and the processing means 12. FIG. 10 illustrates a side-view of the system shown in FIGS. 8a and 8b.

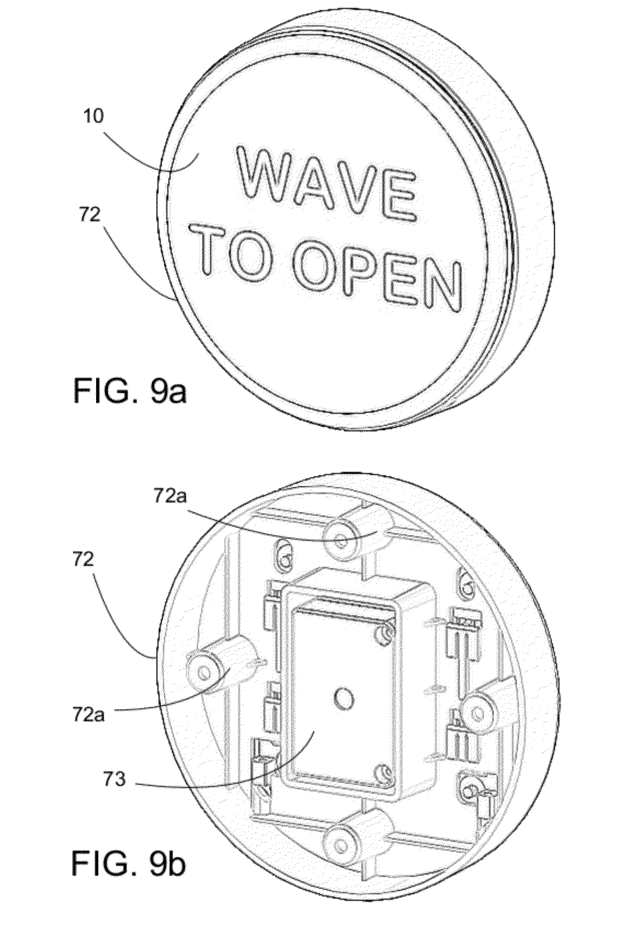

Referring now to FIGS. 9a and 9b, a further non-limiting embodiment of the system 1 according to the principles of the present invention is shown. In this example, the sensor mounting means 72 is wider edges, extending at least past the containment means 73. FIG. 9b illustrates a back-side view of the system shown in FIG. 9a. The back of the sensor mounting means 72 may be provided with surface mounting means 72a for mounting the sensor mounting means 72 on a wall or surface. Although the conductive plate 10 in FIGS. 8a, 8b, 9a, and 9b is round, it will be appreciated that any number of shapes and sizes may be used.

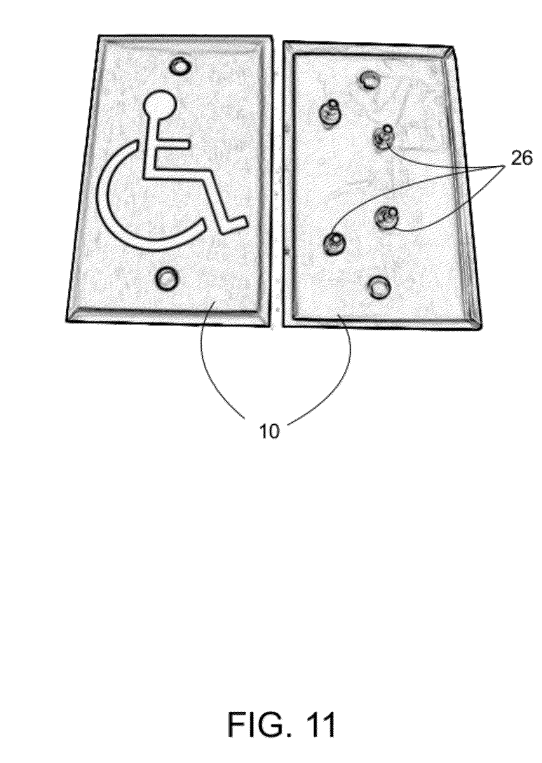

Referring now to FIG. 11, a sensing means 10 is shown according to the principles of the present invention. In one preferred and non-limiting embodiment, the sensing means 10 includes a conductive plate 10 adapted to be coupled to the electrical circuit 8. The conductive plate 10 may further include one or more conductive studs 26 for receiving or otherwise directly connecting to the circuit 8, therefore permitting the circuit 8 to be behind or otherwise attached to the plate 10. In the example shown in FIG. 11, the conductive plate is in the shape of a standard light switch cover, adapted to be mounted on a wall, on a housing, or elsewhere next to an electrically-operated door or other electronic device 6. The plate 10 may conceal the electrical circuit 8 from view. It will further be appreciated that the plate 10 may be located behind a non-conductive material and still produce the electric field 9.

In one preferred and non-limiting embodiment, the system 1 includes one or more software modules. The modules may be in the form of program instructions or object code, embedded in the processing means 12, in other processing devices (e.g., microchips) associated with the system 1, or in a machine-readable medium coupled to the processing means 12. However, it will be appreciated that other suitable forms of executable programs or programmable computing devices may be used.

In one non-limiting embodiment of the present invention, the system 1 is configured to track the signal received from the sensing means 10, or the portion of the electrical circuit 8 associated with the sensing means 10, in order to track a real-time value for slow environmental changes. This tracking may be performed by the processing means 12, or some other processor.

In one example, tracking may only be performed when the sensing means 10 is not in activation (e.g., a NO DETECT state). Such tracking may provide further stability to the sensing means 10 and may help reject false activations/detections. The period of time for the tracking process may be determined by a predefined constant (e.g., TRACK_RATE), which may be set, for example, from 1 to 10. For example, if the track rate is set at 1, then the baseline may be tracked every 1 reading or 10 milliseconds, or some other period of time. As another example, if the rate is set at 5, then the baseline is tracked every 5 readings or at 50 millisecond intervals.

A further constant (e.g., TRACK_WEIGHT) may be used in the tracking process to determine the percentage given to the new reading (e.g., the impact that the new reading will have on the baseline value or range). The track rate may be set, for example, to 2, 4, 8, or 16, so that the processing means 12 may easily perform the appropriate calculation by division. For example, if the weight is set to 2, the new reading may be 50% of the new baseline. As another example, if the weight is set to 8, the new reading may be 12.5% of the new baseline. However, it will be appreciated many values may be used.

The TRACK_WEIGHT and TRACK_RATE parameters provide the sensing means 10 with adjustability to maximize the stability and responsiveness of the sensing means 10. In addition to tracking, if the sensing means 10 is held in activation for longer than a predetermined amount of time (e.g., 5 seconds), and the capacitive value of the sensing means 10 remains stable, the baseline capacitive value may be relearned. This relearning feature may address a situation where an object or entity is positioned within the electric field 9 for longer than the predetermined amount of time, allowing for activation by other objects or entities through a changed baseline value or range.

In a preferred and non-limiting embodiment of the present invention, the system 1 may determine a capacitance value associated with the electric field 9 as an analog voltage or by directly measuring the frequency. In either example, there may still be analog signals that need to be handled by the processing means 12 for the user adjustable sensitivity setting (e.g., via the potentiometer) and, in wireless embodiments, monitoring the battery voltage. To obtain the analog values, the processing means 12 may read in the voltages as, for example, 32 samples, and average them into a single reading. This technique may be referred to as oversampling. Oversampling helps avoid aliasing (i.e., different signals becoming indistinguishable), improves resolution, and reduces noise. The samples may be acquired through a module configured to read the signals from Analog-to-Digital converters. Those readings may then be translated into a value between, for example, 0.0 and 2.0 VDC. Once the voltage is known, it can be used to assess sensitivity and battery level.

In a preferred and non-limiting embodiment of the present invention, a software module or function is provided to determine a baseline capacitance of the sensing means 12, as translated into an integer count representing a frequency. This count may be updated every 10 milliseconds, or at some other specified interval, by an interrupt service routine (ISR). The baseline capacitance is created by oversampling the count, i.e., obtaining multiple values and averaging them into a single value.

In one preferred and non-limiting embodiment of the present invention, an interrupt module is provided. The interrupt module is configured to process the peripheral interrupts generated by the processing means 12. An interrupt is a signal from hardware associated with the processing means 12, indicating the need for attention in one or more software modules. In one embodiment of the present invention, only one interrupt may be generated. The interrupt may be an 8-bit timer that will increment every instruction cycle and will generate an interrupt when a timer register (e.g., TMR0) of the processing means 12 overflows from 0xFF to 0x00. The main software module or function may configure the timer such that it will overflow and cause an interrupt every 10 milliseconds. An interrupt handling function may then update several timers that are used throughout the modules. These timers may be used for inputs, outputs, or other purposes. The interrupt handling module may also contain 3 timer prescalers (e.g., electronic counting circuit) to allow for prescaling of timers. The prescaling may be performed for two reasons. First, in an 8-bit processor, it is preferred that the use of variables greater than 8 bits is minimized, and adding these extra prescaler timers allow for that. The second reason relates to the readability of the program instructions associated with the modules.

Although the ISR may only perform simple timer functions, that is not always the case. For example, the ISR may contain the code for measuring the frequency of the relaxation oscillator's RC time constant (i.e., the product of circuit capacitance and resistance) created by the sensing means 10. This frequency may be translated into an integer count representing a frequency. The creation of the count may be based on an output of the comparator C2 output (C2OUT) gate of the processing means 12. C2OUT drives the oscillator and, additionally, is inputted into a clock timer. Each time C2OUT changes from 0 to 1 (e.g., low to high), the timer will increment.

The timer may continue to increment and, eventually, start over. However, to be useful for capacitive sensing, a fixed time base may be used to measure the frequency over a defined period of time. At the start of a measurement, a timer (e.g., an 8-bit timer) is cleared, and on the timer interrupt, the value of a second timer register (e.g., TMR1) is read. This count constitutes a single capacitance sample from the sensing means 12. As with other values read in by the software functions or modules, the value for the capacitance may be oversampled. The oversampling is performed by a very simple two state state-machine. The first state will simply collect samples and, once the required number of samples is collected (e.g., 4), the next state simply averages the samples into a single reading. Further, the averaging state may sample again so that a cycle is not wasted. Once the reading is generated, a flag is set to TRUE so that a main function or module may obtain the new value and then pass it on to the determine/detect function or module. For example, if the current value of the timer is significantly lower, the capacitance has increased and the frequency has decreased, meaning the sensing means 12 has detected proximity or presence of an object or entity. At the end of the ISR, once all tasks for determining proximity of an object or entity and setting appropriate flags are finished, both timers are cleared and restarted for the next reading. In one non-limiting embodiment, the ISR module allows for an indication means 15 (e.g., a sound-emitting device) to indicate that a battery has a low power level.

A determine/detect software module or function monitors the sensing means 10 input to the processing means 12 and determines if an object or entity is in a threshold proximity to the sensing means 10. The state of the sensing means 10 is determined by comparing the count generated by the ISR to the deviation from the baseline value or range. In one preferred and non-limiting embodiment, there may be four states, determinable by a function call, including NO DETECT, START DETECT, IN DETECT, and RELEARN.

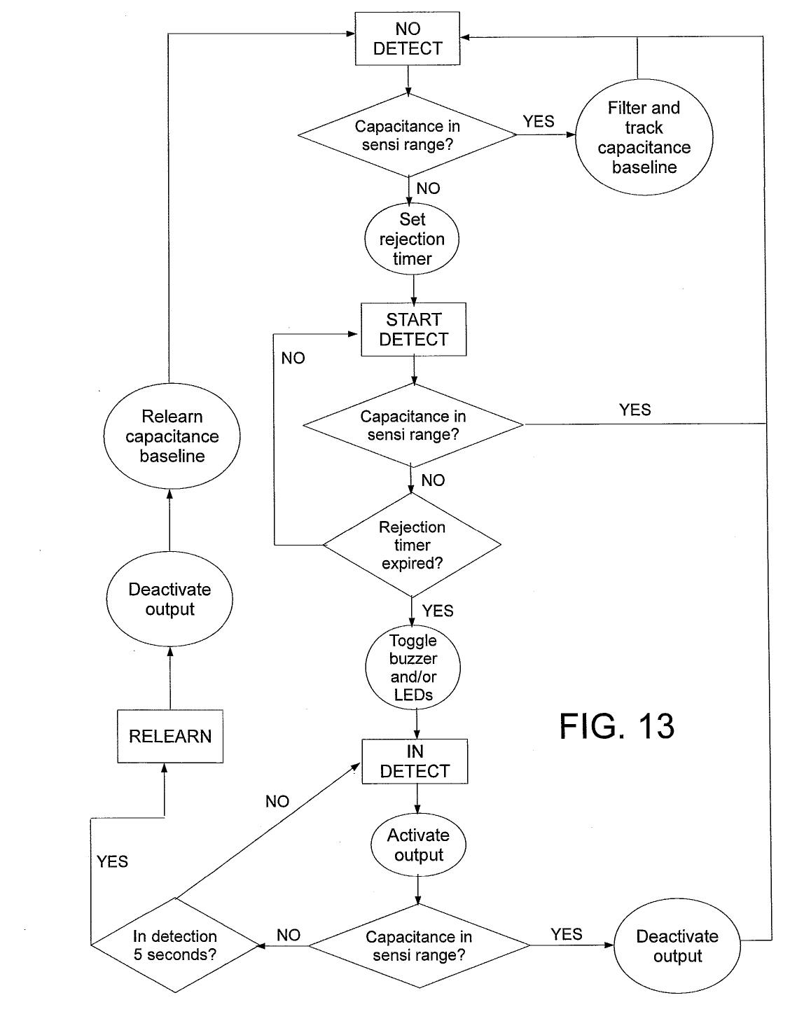

Referring now to FIG. 13, a flow diagram is shown for determining the state of the sensing means 10 according to the principles of the present invention. From the NO DETECT state, it is determined if the capacitance is within the baseline value or range. If the capacitance is outside this range, the rejection timer is set and the process continues to the START DETECT state. If the capacitance is within this range, the processing means 12 filters and tracks the capacitance baseline value or range and proceeds to the NO DETECT state.

From the START DETECT state, it is determined whether the received capacitance is in a normal range based on a baseline value or range. If the capacitance is out of the normal range, it is then determined whether the rejection timer is expired. If the timer is not expired, the process loops back to START DETECT. If the timer is expired, the buzzer 15b (e.g., sound-emitting device) and/or LEDs 15a (e.g., visual indication means) are toggled on or off, and the process continues to an IN DETECT state.

From the IN DETECT state, the output is activated (e.g., the relay means 16 and/or output circuit 51) initiates a change of the functional state of an electronic device 6. Then, it is again determined if the capacitance is in a normal range based on the baseline value or range. If it is, the output is deactivated and the process continues to a NO DETECT state. If the capacitance is still outside of a normal range, it is determined whether the change in capacitance continues for a predetermined period of time (e.g., 5 seconds). If the capacitance is outside of a normal range for longer than the predetermined period of time, a RELEARN state is entered in which the output is deactivated and a baseline capacitance is relearned by the processing means 12. Then, the process continues to the NO DETECT state. If, after the output is activated, the capacitance is back to a normal range based on the baseline value or range, the output is deactivated and the process continues to the NO DETECT state.

In one preferred and non-limiting embodiment of the present invention, one or more software modules are used to learn a baseline value or range associated with the electric field 9, to re-learn the baseline value or range based on environmental changes, and to detect the proximity or presence of an object or entity. Upon start-up of the system 1, a function or module (e.g., main( )) may first initialize the hardware on the processor 12. The hardware initialization may be performed by special function registers. Once the processor 12 is initialized, a software module may then read in the sensitivity of the sensing means 10 as determined by an analog voltage converted from a potentiometer. Then, the software module may learn the baseline capacitance (e.g., baseline value or range) of the plate 10, as translated into an integer count representing a frequency. This count will be updated every 10 milliseconds by the interrupt service routine (ISR) (e.g., interrupt handler).

If the electronic circuit 8 is hardwired, the LEDs may be set to the correct state. A software module may then enter a continuous loop of waiting for the sensing means' 10 real-time capacitance from the ISR, and then, when the real-time capacitance is received, may call a determine/detect function (e.g., determine _detect( )). In a preferred and non-limiting embodiment, the sensitivity value is checked every 5 seconds by the potentiometer reading.

The determine/detect function is associated with a rejection timer that expires after a predetermined duration of time (e.g., 50-90 milliseconds). In a preferred and non-limiting embodiment, the rejection timer is initially set to 90 milliseconds so that fleeting changes in the electric field 9 do not unintentionally active the system 1. Therefore, an object or entity must remain within the electric field 9, affecting the capacitance, for longer than 90 milliseconds. However, it will be appreciated that the rejection timer may be set at various intervals for different applications.

In one preferred and non-limiting embodiment of the present invention, the determine/detect function, or some other function or module, may sense spikes in the capacitance change associated with the electric field 9. This situation may arise in emergency applications where users quickly come into contact with the sensing means 10, but not long enough to activate the device. In such a situation, the rejection timer may be set to a lesser value (e.g., 50 milliseconds) to adjust to that environment. Another option would be to use an accelerometer, as discussed herein, to detect swift contact.

In a wireless embodiment, in which the relay means 16 wirelessly transmits a signal to change a functional state of an electronic device 6, a low battery warning means may be provided for indicating to users that the battery power is low. In one preferred and non-limiting embodiment, a battery monitoring circuit provides an analog output which is converted, by the processing means 12, into one of three battery levels: good, warning, and inoperable. The battery analog voltage may be checked at predetermined intervals (e.g., every 60 seconds). If the battery power is at a “good” level, the system 1 will function normally. If the battery power is on a “warning” level, the system 1 will function normally but, at predetermined intervals (e.g., 10 minutes), may emit an audible sound a predetermined number of times (e.g., 3 times), even if the sound-emitting device 15b is turned off. In addition to a periodic sound, when the sensing means 10 detects an object or entity in the electric field 9, it may also emit one or more sounds, even if the sound-emitting device 15b is turned off. If the battery power is on an “inoperable” level, the sensing means 10 will cease to function, but will periodically continue to monitor the battery voltage so as to change back to one of the operable states when appropriate.

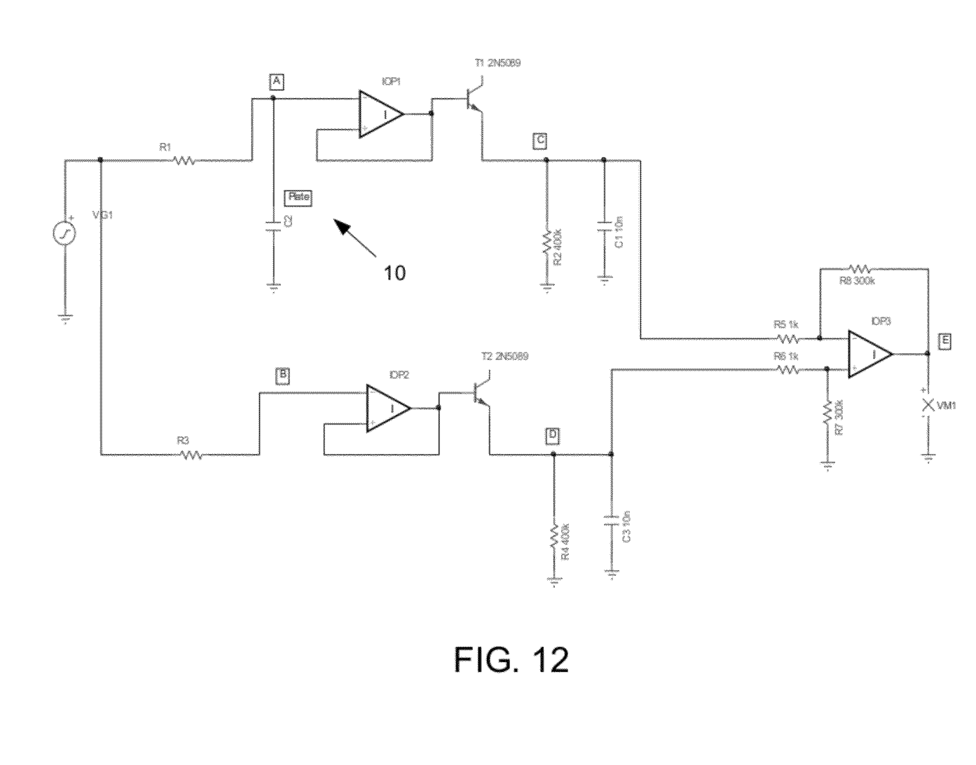

Referring now to FIG. 12, a schematic diagram is shown for a further embodiment of the system according to the principles of the present invention. The circuit consists of signal source VG1, sensing means 10, two signal followers (OP1, OP2), two signal rectifiers (T1, R2, C1, and T2, R4, C3), and one differential amplifier ((R5, R6, R7, R8, DP3). The capacitance of C2 may be zero when the object or entity is a distance apart from the sensing means 10. The signal amplitude at point A and B is same, and the DC value at point C and D is same. The output at point E may be zero. The capacitance of C2 increases when an object or entity is in proximity to the sensing means 10. The DC value at point C is smaller than the DC value at point D. The output of at point E is larger than zero volts. The closer an object or entity is to the sensing means 10, the higher the output voltage that will be seen at point E.

Although the invention has been described in detail for the purpose of illustration based on what is currently considered to be the most practical and preferred embodiments, it is to be understood that such detail is solely for that purpose and that the invention is not limited to the disclosed embodiments, but, on the contrary, is intended to cover modifications and equivalent arrangements that are within the spirit and scope of the appended claims. For example, it is to be understood that the present invention contemplates that, to the extent possible, one or more features of any embodiment can be combined with one or more features of any other embodiment.

The invention claimed is:

1. A sensing device comprising:
a) at least one electrically conductive unit;
b) an electrical circuit coupled to at least one processor, the at least one electrically conductive unit, and at least one reference,
wherein the sensing device is configured to:
i) cause the at least one electrically conductive unit and the at least one reference to form a capacitive relationship associated with an electrical field;
ii) detect a capacitive change in at least a portion of the electrical field; and
iii) cause a functional state of at least one electronic device to be at least partially changed based at least partially on the capacitive change.

2. The sensing device of claim 1, wherein the capacitive change is at least partially detected by comparing at least one value or range associated with the electrical field with at least one of a baseline value and baseline range.

3. The sensing device of claim 2, wherein the at least one processor is configured to track capacitive changes in the electrical field, such that the at least one of a baseline value and baseline range is at least partially calculated from the capacitive changes.

4. The sensing device of claim 2, wherein the at least one processor is configured to learn the at least one of a baseline value and baseline range by detecting at least one value or range associated with the electrical field for a predetermined amount of time.

5. The sensing device of claim 4, wherein the at least one processor is further configured to relearn a new baseline value or range associated with the electrical field when the capacitive change occurs for a predetermined amount of time.

6. The sensing device of claim 1, further comprising at least one sound-emitting device, wherein the sensing device is configured to cause the at least one sound-emitting device to emit at least one audible sound when at least one of an object and entity is detected in at least a portion of the electrical field.

7. The sensing device of claim 1, further comprising at least one visual indicator, wherein the sensing device is configured to cause the at least one visual indicator to change visual states when at least one of an object and entity is detected in at least a portion of the electrical field.

8. The sensing device of claim 1, further comprising at least one relay means wirelessly coupled to the at least one electronic device.

9. The sensing device of claim 1, further comprising at least one accelerometer coupled to at least one of the electrical circuit and the at least one processor, wherein the at least one accelerometer is configured to detect at least one physical impact on at least a portion of the sensing device, and wherein the at least, one physical impact at least partially causes the functional state of the at least one electronic device to be at least partially changed.

10. The sensing device of claim 1, wherein the electrical field is three-dimensional.

11. A method for sensing proximity of an object or entity, the method comprising:
producing, with at least one electrically conductive unit, a dielectric field by causing at least a portion of the at least one electrically conductive unit to become capacitively coupled with at least one reference, wherein the at least one reference is at least one of the following: ground, a different electrically conductive unit, or any combination thereof;
detecting at least one capacitive change in at least a portion of the dielectric field; and
changing a functional state of at least one electrical device based at least partially on the at least one capacitive change.

12. The method of claim 11, further comprising: calculating, with at least one processor, at least one of a baseline value and baseline range for the dielectric field, wherein at least a portion of the at least one of a baseline value and baseline range is used to at least partially determine the at least one capacitive change.

13. The method of claim 11, further comprising: changing a visual state of at least one visual indication means based at least partially on the at least one capacitive change.

14. The method of claim 11, further comprising: causing at least one sound-emitting device to emit at least one sound based at least partially on the at least one capacitive change.

15. The method of claim 11, further comprising: learning at least one of a baseline value and baseline range by detecting at least one value or range associated with the dielectric field for a predetermined amount of time.

16. The method of claim 15, wherein the at least one capacitive change is at least partially detected by comparing a value or range associated with the dielectric field with at least a portion of the at least one of a baseline value and baseline range.

17. The method of claim 16, further comprising: learning a new baseline value or range associated with the dielectric field when the capacitive change occurs for a predetermined amount of time.

18. The method of claim 11, further comprising: determining at least one capacitance sample from the at least one electrically conductive unit at least partially by measuring at least one frequency of at least one oscillator coupled to the at least one electrically conductive unit over a period of time, wherein the period of time is at least partially determined by at least one interrupt generated by at least one processor.

19. A system to signal proximity of at least one object or entity, comprising:
reference means;
sensing means for sensing the at least one object or entity in an electric field, the sensing means configured to at least partially form the electric field with at least a portion of the reference means; and
processing means for detecting at least one capacitive change in at least a portion of the electric field.

20. The system of claim 19, wherein the processing means is configured to determine a baseline value or range associated with the electric field, such that the at least one capacitive change is at least partially detected by comparing at least one detected value or range associated with the electric field with the baseline value or range.

21. The system of claim 19, further comprising relay means for changing a functional state of at least one device.

22. The system of claim 21, wherein the at least one device includes at least one of the following: electric door, electric gate, electric light, or any combination thereof.

23. The system of claim 19, further comprising indication means for indicating at least one of the following: the system is turned on, the at least one object or entity has been sensed in the electric field, that an error has occurred, or any combination thereof.

24. The system of claim 23, wherein the indication means includes at least one visual indication means that is substantially blue.

25. The system of claim 22, wherein the indication means includes at least one visual indication means, wherein the at least one visual indication means at least partially illuminates a surface behind at least one of the sensing means and a mounting means for mounting the sensing means.

26. The system of claim 19, wherein the reference means comprises at least one of the following: earth ground, signal ground, chassis ground, electrically conductive material, or any combination thereof.

27. The system of claim 19, wherein the sensing means includes at least one of the following: faucet, towel dispenser, air dryer, flushing mechanism, soap dispenser, or any combination thereof.

28. The system of claim 19, further comprising a low battery warning means for indicating that at least one battery has a charge below a predetermined level.

29. The system of claim 19, wherein the processing means is configured to generate at least one interrupt, and wherein a fixed time base is at least partially determined by the at least one interrupt, such that at least one capacitance value associated with the sensing means is at least partially determined by measuring at least one frequency generated by at least one oscillator over at least a portion of the fixed time base.

30. The system of claim 19, wherein the at least one capacitive change is at least partially determined based on at least one output of at least one differential amplifier coupled to the sensing means.
